(19) United States
(12) Patent Application Publication
(10) Pub. No.: US 2022/0034933 A1
(43) Pub. Date: Feb. 3, 2022

(54) ROTATION DETECTION DEVICE

(71) Applicant: DENSO CORPORATION, Kariya-city (JP)

(72) Inventor: Tomoya TAKAYAMA, Kariya-city (JP)

(21) Appl. No.: 17/382,445

(22) Filed: Jul. 22, 2021

(30) Foreign Application Priority Data
Jul. 28, 2020 (JP) 2020-127041

(51) Int. Cl. G01P 3/487; G01P 1/02; G01R 33/02; G01D 5/14; H01R 31/00

(52) U.S. Cl. CPC G01P 3/487; G01P 1/026; H01R 31/005; G01D 5/145; G01R 33/02

(57) ABSTRACT

A rotation detection device includes a first mold IC, a second mold IC, and a housing. The first mold IC and the second mold IC are each housed in a point-symmetrical position with respect to a reference point in the housing. The housing includes a connector having (i) a first terminal electrically connected to the first mold IC, (ii) a second terminal electrically connected to the second mold IC, and (iii) a GND terminal that is electrically connected to both of the first and second mold ICs. The connector is arranged at a position corresponding to the reference point on the housing.

### CROSS REFERENCE TO RELATED APPLICATION

The present application is based on and claims the benefit of priority of Japanese Patent Application No. 2020-127041, filed on Jul. 28, 2020, the disclosure of which is incorporated herein by reference.

### TECHNICAL FIELD

The present disclosure is in the technical field of detecting rotating objects.

### BACKGROUND ART

Conventionally, a sensor that detects the rotation of an object to be detected has been proposed. The sensor uses two systems and two respective connectors.

### SUMMARY

It is an object of the present disclosure to provide a rotation detection device with a single connector serving the two systems.

### BRIEF DESCRIPTION OF THE DRAWINGS

Objects, features, and advantages of the present disclosure will become more apparent from the following detailed description made with reference to the accompanying drawings, in which:

FIG. 1 is a perspective view of a rotation detection device according to an embodiment;

FIG. 2 is a diagram of a relationship between a rotating body and a housing;

FIG. 3 is a view of an outer peripheral surface of the housing;

FIG. 4 is a view of an end face of the housing;

FIG. 5 is a perspective view of a first terminal, a second terminal, and a GND terminal; and

FIG. 6 is a block diagram of an electrical configuration of the rotation detection device.

### DETAILED DESCRIPTION

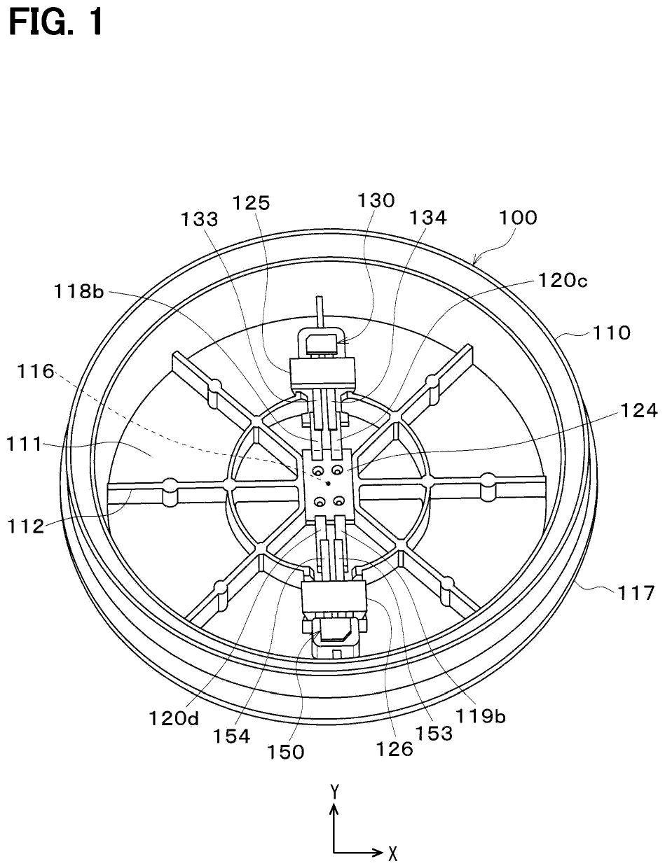

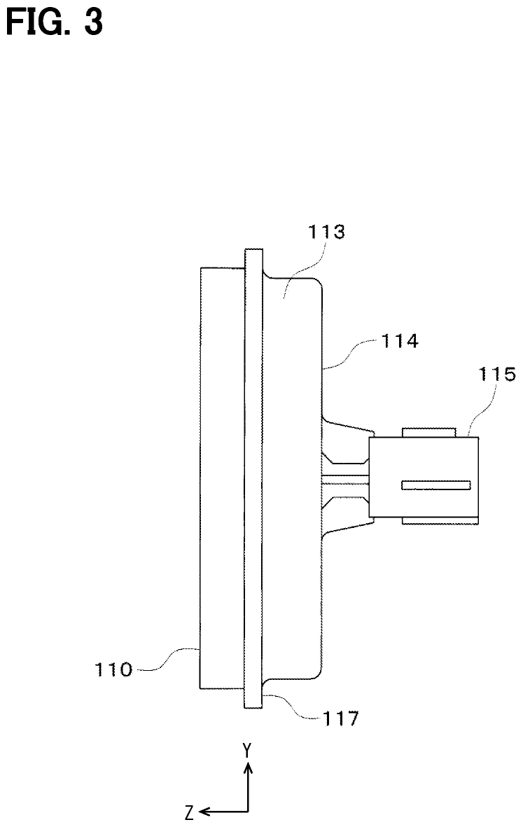

Hereinafter, one embodiment is described with reference to the drawings. The rotation detection device in the present embodiment detects, for example, the rotation speed of a vehicle tire. As shown in FIGS. 1 to 4, a rotation detection device 100 includes a housing 110, a first mold IC (Integrated Circuit) 130, and a second mold IC 150.

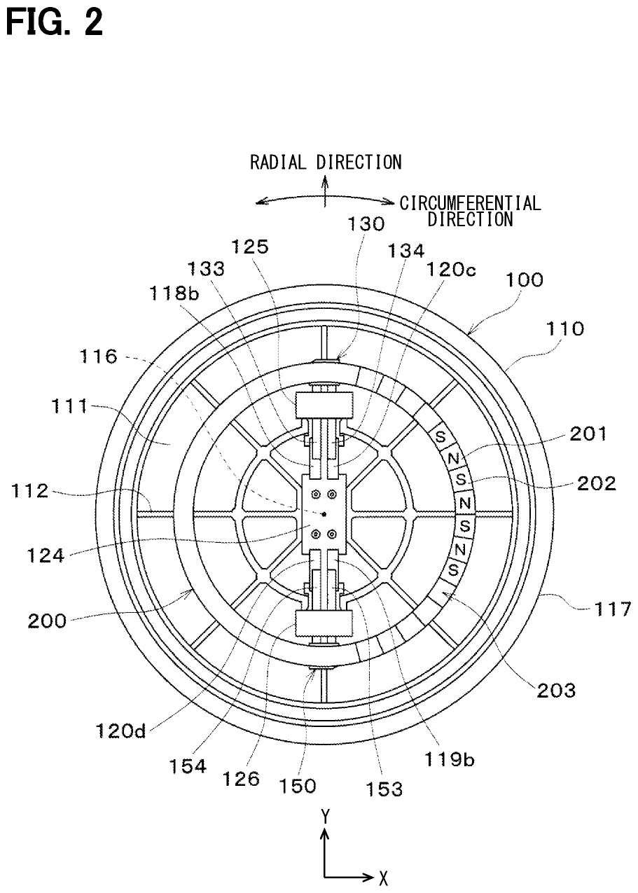

As shown in FIG. 2, the rotating body 200 as a detection target is, for example, a magnetic rotor. The rotating body 200 is built in, for example, at an end of a hub unit. In FIG. 2, Cartesian coordinates include: an X direction (rightwards as viewed by a reader), a Y direction, and a Z direction.

The rotating body 200 has a magnetic pattern 203 in which a plurality of first magnetic poles 201 and second magnetic poles 202 are alternately arranged in an annular shape. The first magnetic pole 201 generates, for example, an N-pole magnetic force. The second magnetic pole 202 generates, for example, an S-pole magnetic force. The magnetic pattern 203 is provided with, for example, 96 poles of the first magnetic pole 201 and the second magnetic pole 202.

The housing 110 is a bottomed cylindrical part. The housing 110 is formed by resin molding a resin material such as PPS (Polyphenylenesulfide). The housing 110 includes an installation surface 111, a beam portion 112, an outer peripheral surface 113, an end surface 114, and a connector 115.

The main body of the housing 110 is made of a resin material. Further, an open end portion of the housing 110 is made of a metal material. The open end portion of the housing 110 is fixed to the end of the hub unit.

The installation surface 111 is a circular bottom surface located at the bottom of the housing 110. The installation surface 111 has a reference point 116. The reference point 116 is an arbitrary position on the installation surface 111. The reference point 116 is, for example, the position of the center of the installation surface 111. That is, the reference point 116 is a position on the installation surface 111 through which a central axis of the housing 110 passes. Alternatively, the reference point 116 is a position through which a central axis of the rotating body 200 passes. The beam portion 112 is provided on the installation surface 111. The beam portion 112 is provided to ensure the rigidity of the housing 110.

The outer peripheral surface 113 has a protruding portion 117. The protruding portion 117 is a portion of the outer peripheral surface 113 that protrudes in a radial direction. The protruding portion 117 is continuously provided so as to go around the outer peripheral surface 113 in a circumferential direction. The end surface 114 is a surface opposite to the installation surface 111.

The connector 115 is arranged on the end surface 114 of the housing 110. The connector 115 has a shape extending along a vertical direction perpendicular to the end surface 114. The connector 115 is arranged on the end surface 114 in the housing 110 at a position corresponding to the reference point 116. The position corresponding to the reference point 116 is a position within a certain range including the reference point 116 in a surface direction of the end surface 114. In other words, such a position may be understood as a substantially-center position of the end surface 114.

Further, the connector 115 has a first terminal 118, a second terminal 119, and a GND terminal 120. GND is an abbreviation of a ground. Each terminal 119 to 120 is insert-molded into the housing 110. The terminals 119 to 120 may also be assembled to the housing 110 later, i.e., after molding.

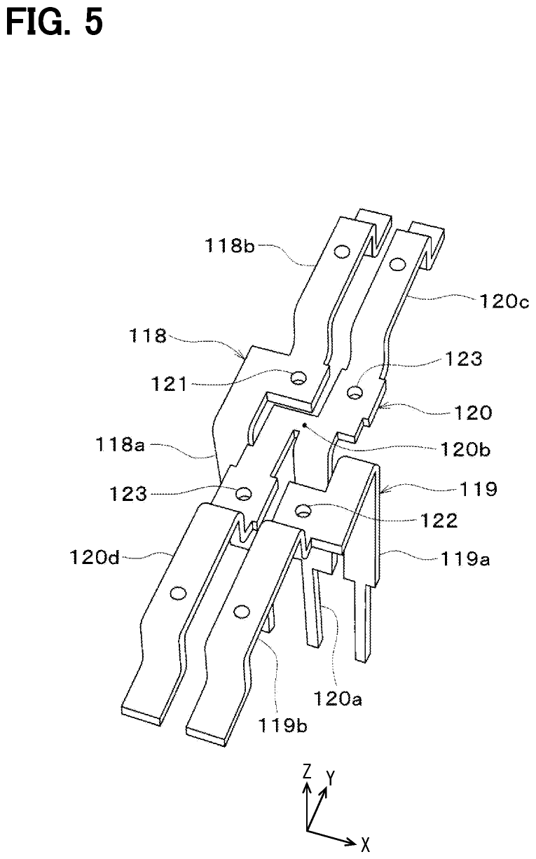

As shown in FIG. 5, each terminal 119 to 120 is (separately) formed by pressing a metal plate such as Cu or the like. Through holes 121 to 123 provided in the terminals 119 to 120 are holes for positioning in the assembling process. Each terminal 119 to 120 is fixed to the housing 110 by using a fixing portion 124.

The first terminal 118 has a first tip portion 118a and a first connection portion 118b. The first tip portion 118a is arranged in the connector 115. The first tip portion 118a extends along the vertical direction. The first connection portion 118b is connected to the first tip portion 118a and is arranged on the installation surface 111 of the housing 110. The first connection portion 118b extends along the installation surface 111.

The first terminal 118 is a terminal electrically connected to the first mold IC 130. The first terminal 118 is a power supply terminal that supplies electric power to the first mold IC 130. Further and/or alternatively, the first terminal 118 is an output terminal that outputs a first detection signal of the first mold IC 130 as a current signal (i.e., a signal of an electric current) to an external device.

The second terminal 119 has a second tip portion 119a and a second connection portion 119b. The second tip portion 119a is arranged in the connector 115. The second tip portion 119a extends along the vertical direction. The second connecting portion 119b is connected to the second tip portion 119a and is arranged on the installation surface 111 of the housing 110. The second connection portion 119b extends along the installation surface 111.

The second terminal 119 is a terminal electrically connected to the second mold IC 150. The second terminal 119 is a power supply terminal that supplies electric power to the second mold IC 150. Further and/or alternatively, the second terminal 119 is an output terminal that outputs a second detection signal of the second mold IC 150 as a current signal to an external device.

The GND terminal 120 is a common terminal that is electrically connected to both of the first mold IC 130 and the second mold IC 150. The GND terminal 120 has a third tip portion 120a, a branching portion 120b, a first branched portion 120c, and a second branched portion 120d.

The third tip portion 120a is arranged in the connector 115. The branching portion 120b is connected to the third tip portion 120a. A part of the branching portion 120b extends along the vertical direction. The first branched portion 120c is connected to one of branching ends of the branching portion 120b and is electrically connected to the first mold IC 130. The second branched portion 120d is connected to the other of branching ends of the branching portion 120b and is electrically connected to the second mold IC 150. The first branched portion 120c and the second branched portion 120d both extend along the installation surface 111.

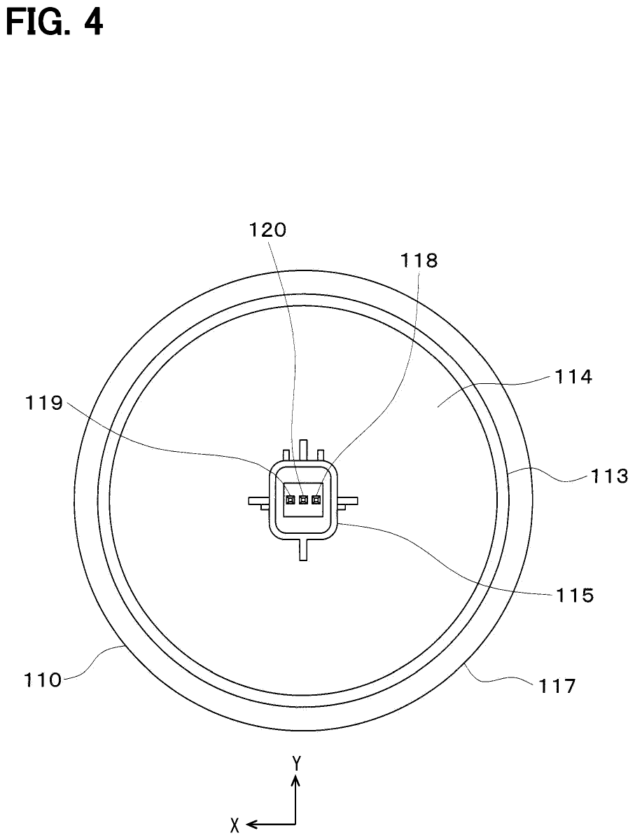

As shown in FIGS. 4 and 5, the third tip portion 120a of the GND terminal 120 is arranged at a position between the first tip portion 118a of the first terminal 118 and the second tip portion 119a of the second terminal 119. As a result, the third tip portion 120a of the GND terminal 120 is less susceptible to noise. Therefore, the noise resistance character of the rotation detection device 100 can be improved.

The housing 110 accommodates the first mold IC 130, the second mold IC 150, and a part of each terminal 119 to 120. The housing 110 is fixed to the end of the hub unit integrated with the wheel of a vehicle tire.

The first mold IC 130 and the second mold IC 150 are mold ICs having a sensing element for detecting a change in a magnetic field. As shown in FIG. 2, the rotating body 200 is arranged to face the first mold IC 130 and the second mold IC 150.

The first mold IC 130 and the second mold IC 150 have the same configuration. The first mold IC 130 outputs a first detection signal according to the rotation position of the rotating body 200. The second mold IC 150 outputs a second detection signal according to the rotation position of the rotating body 200. That is, the rotation detection device 100 has two systems.

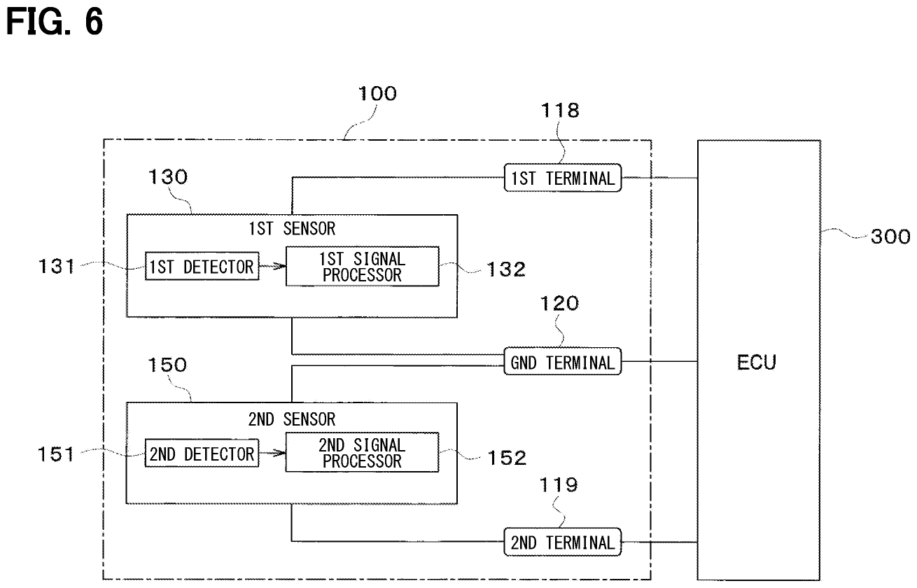

As shown in FIG. 6, the first mold IC 130 and the second mold IC 150 are connected to the ECU (Electronic Control Unit) 300. The ECU 300 is a device that controls the first mold IC 130 and the second mold IC 150.

Although not shown, the ECU includes a power supply unit, a control unit, and a ground unit. The power supply unit is a circuit unit that supplies a power supply voltage to the molded ICs 130 and 150. The control unit is a circuit unit that performs predetermined control according to the first detection signal and the second detection signal input from the mold ICs 130 and 150. For example, the control unit determines whether or not there is an abnormality in each of the molded ICs 130 and 150 by comparing the first detection signal and the second detection signal. The ground unit is a circuit unit that sets a ground voltage of each of the molded ICs 130 and 150.

The first mold IC 130 includes a first detector 131, a first signal processor 132, a first wiring 133, and a second wiring 134. The second mold IC 150 has a second detector 151, a second signal processor 152, a third wiring 153, and a fourth wiring 154.

The first detector 131 and the second detector 151 detect a change in the magnetic field due to a change in the rotation position of the rotating body 200. The first detector 131 and the second detector 151 are configured as, for example, a Hall element, a GMR (Giant Magneto Resistance) element, a TMR (Tunneling Magneto Resistance) element, or an AMR (Anisotropic Magneto Resistance) element. Since an output waveform cycle of the AMR element is doubled compared to other elements, it is necessary to adjust the number of poles of the magnetic pattern 203 to ½, but the point of detecting magnetism is the same as that of other elements.

The first signal processor 132 obtains a detection result of the first detector 131, performs signal processing such as signal amplification and conversion, and generates the first detection signal. The first signal processor 132 outputs the first detection signal as a current signal to the first terminal 118 via the first wiring 133.

The second signal processor 152 obtains a detection result of the second detector 151, performs signal processing such as signal amplification and conversion, and generates the second detection signal. The second signal processor 152 outputs the second detection signal as a current signal to the second terminal 119 via the third wiring 153.

Each of the wirings 133, 134, 153, and 154 is a part of a lead frame formed by pressing a metal plate such as Cu or the like. The first wiring 133 electrically connects the first connection portion 118b of the first terminal 118 and the first signal processor 132. The second wiring 134 electrically connects the first branched portion 120c of the GND terminal 120 and the first signal processor 132. The first wiring 133 and the second wiring 134 are fixed to the housing 110 by using a first resin lid 125.

The third wiring 153 electrically connects the second connection portion 119b of the second terminal 119 and the second signal processor 152. The fourth wiring 154 electrically connects the second branched portion 120d of the GND terminal 120 and the second signal processor 152. The third wiring 153 and the fourth wiring 154 are fixed to the housing 110 by using a second resin lid 126.

Note that the mold ICs 130 and 150 are sealed by a mold resin so that tip portions of the wirings 133, 134, 153 and 154 are exposed.

The first mold IC 130 and the second mold IC 150 are arranged on the installation surface 111 of the housing 110 and housed in the housing 110. The first mold IC 130 and the second mold IC 150 are arranged at point-symmetrical positions with respect to the reference point 116. More specifically, the first detector 131 of the first mold IC 130 and the second detector 151 of the second mold IC 150 are arranged point-symmetrically with respect to the reference point 116.

Since the first mold IC 130 and the second mold IC 150 are arranged point-symmetrically in the above-described manner, the GND terminal 120 can be arranged at a position between the first mold IC 130 and the second mold IC 150. Further, the GND terminal 120 can be shared among the mold ICs 130 and 150 without straddling/circumventing the first terminal 118 or the second terminal 119. That is, it is not necessary for the GND terminal 120 to cross over the first terminal 118 or the second terminal 119. Therefore, although the rotation detection device 100 has two systems, the number of the GND terminals 120 can be reduced. Therefore, the physique/volume of the connector 115 is reducible. Therefore, the size of the connector 115 can be reduced.

Here, when detecting the rotation of the rotating body 200, if the first mold IC 130 and the second mold IC 150 are arranged line-symmetrically with respect to the reference point 116, both of the mold ICs 130 and 150 have offset arrangement with respect to the reference point 116. Therefore, it leads to a decrease/deterioration in performance when detecting the rotation of the rotating body 200. On the other hand, if the arrangement is point-symmetrical, no offset is generated with respect to the reference point 116, and the detection performance is not deteriorated.

As a modification, the terminals 118 and 119 can dispense with the connection portions 118b and 119b, and the GND terminal 120 can dispense with the branching portion 120b and the branched portions 120c and 120d. The tip portions 118a, 119a, and 120a of the terminals 119 to 120 may be connected to the wirings 133, 134, 153, and 154 by wires or the like. That is, the GND terminal 120 does not have to have a branched structure.

As a modification, the rotating body 200 may be configured in an annular shape surrounding the outer peripheral surface 113 of the housing 110. In such case, the rotating body 200 may have a cylindrical/pipe shape. The detectors 131 and 151 of the mold ICs 130 and 150 may be fixed to the housing so as to be affected by the magnetic field from the inner peripheral surface of the rotating body 200. For example, the detectors 131 and 151 may be arranged on the outer peripheral surface 113 of the housing 110.

As a modification, the housing 110 does not have to have a bottomed cylindrical shape. The housing 110 may have a shape other than the cylindrical shape.

As a modification, the rotation detection device 100 may include four or more systems instead of two systems. For example, four or six molded ICs may be arranged point-symmetrically with respect to a reference point.

### Other Embodiments

The configuration of the rotation detection device 100 shown in each of the above embodiments is an example, and the configuration is not limited to the configuration shown above, and any other configurations capable of realizing the present disclosure can thus be usable.

For example, the shape of each of the terminals 119 to 120 is not limited to the shape shown in FIG. 5. Further, the rotating body 200 is not limited to the one mounted on the vehicle.

What is claimed is:

1. A rotation detection device comprising:
a first mold IC (Integrated Circuit) configured to output a first detection signal corresponding to a rotation position of a rotating body by detecting a first change in a first magnetic field accompanying a change in the rotation position of the rotating body;
a second mold IC configured to output a second detection signal according to the rotation position of the rotating body by detecting a second change in a second magnetic field accompanying the change in the rotation position of the rotating body; and
a housing accommodating the first mold IC and the second mold IC, wherein
the first mold IC and the second mold IC are arranged at a point-symmetrical position with respect to a reference point in the housing,
the housing includes a connector having a first terminal electrically connected to the first mold IC, a second terminal electrically connected to the second mold IC, and a GND (ground) terminal electrically connected to both of the first mold IC and the second mold IC, and
the connector is arranged at a position corresponding to the reference point in the housing.

2. The rotation detection device of claim 1, wherein
the GND terminal includes:
a ground tip portion arranged in the connector,
a branching portion connected to the tip portion,
a first branched portion connected a first branching end of the branching portion and electrically connected to the first mold IC, and
a second branched portion connected to a second branching ends of the branching portion and electrically connected to the second mold IC.

3. The rotation detection device of claim 2, wherein
the ground tip portion is arranged at a position between the first terminal and the second terminal.

4. The rotation detection device of claim 1, wherein
the first terminal is configured to supply a first electric power to the first mold IC and is configured to output the first detection signal as a first current signal, and
the second terminal is configured to supply a second electric power to the second mold IC and is configured to output the second detection signal as a second current signal.

5. The rotation detection device of claim 1, wherein
the rotating body has a magnetic pattern in which a first magnetic poles generate an N-pole magnetic force and second magnetic poles generate an S-pole magnetic force, and the magnetic poles are alternately arranged in an annular shape.

6. The rotation detection device of claim 1, wherein
the rotating body is a component mounted on a vehicle, and
the housing is fixed to the component mounted on the vehicle.

7. A device comprising:
a first terminal;
a second terminal; and
a central terminal,
wherein the device is located in a Cartesian coordinate system including:
(i) a Z axis extending in a positive Z direction and in a negative Z direction,
(ii) an X axis extending in a positive X direction and in a negative X direction,
(iii) a Y axis extending in a positive Y direction and in a negative Y direction,
(iv) an XY plane including the X axis and the Y axis,
(v) an XZ plane including the X axis and the Z axis, and
(vi) a YZ plane including the Y axis and the Z axis,
wherein the central terminal includes:
(i) a central tip portion extending vertically downward along the Z axis in the negative Z direction,
(ii) a branching portion extending vertically upward from the central tip portion and branching horizontally into a first branched portion and into a second branched portion,
(iii) the first branched portion extending in the positive Y direction, and offset in the positive X direction relative to the Y axis, and
(iv) the second branched portion extending in a negative Y direction and offset in the negative X direction relative to the Y axis, such that the first branched portion and the second branched portion are on opposite sides relative to the Y axis,
wherein the first terminal includes:
(i) a first tip portion extending vertically downward parallel with the central tip portion, and offset in the negative X direction relative to the central tip portion, and
(ii) a first connection portion extending in the Y direction, and offset in the negative X direction relative to the Y axis,
wherein the second terminal includes:
(i) a second tip portion extending vertically downward parallel with the central tip portion, and offset in the X direction relative to the central tip portion, and
(ii) a second connection portion extending in the negative Y direction, and offset in the X direction relative to the Y axis.

8. The device of claim 7, wherein:
the first connection portion is substantially a first mirror image of the first branched portion relative to the YZ plane, and
the second connection portion is substantially a second mirror image of the second branched portion relative to the YZ plane.

9. The device of claim 7, wherein:
the first connection portion is substantially a first mirror image of the second branched portion relative to an XZ plane that includes the X axis and the Z axis, and
the second connection portion is substantially a second mirror image of the first branched portion relative to the XZ plane.

10. The device of claim 7, wherein:
the first tip portion, the central tip portion, and the second tip portion are each substantially co-planer with the XZ plane.

11. The device of claim 7, further comprising:
a first integrated circuit including:
(i) a first wiring extending in the negative Y direction and electrically contacting the first connection portion, and
(ii) a second wiring extending in the negative Y direction and electrically contacting the first branching portion; and
a second integrated circuit including:
(i) a third wiring extending in the positive Y direction and electrically contacting the second connection portion, and
(ii) a fourth wiring extending in the positive Y direction and electrically contacting the second branched portion.

12. The device of claim 11, further comprising:
a rotating body including:
(i) first magnetic poles, and
(ii) second magnetic poles,
wherein the first magnetic poles are arranged with the second magnetic poles into an alternating and ring-shaped pattern,
wherein the ring-shaped pattern is configured to rotate about the Z axis while passing adjacent to the first integrated circuit and adjacent to the second integrated circuit.
